(19) United States
(12) Patent Application Publication
(10) Pub. No.: US 2022/0406735 A1
(43) Pub. Date: Dec. 22, 2022

(54) SEMICONDUCTOR DEVICE AND METHOD FOR MANUFACTURING SAME

(71) Applicant: CHANGXIN MEMORY TECHNOLOGIES, INC., Hefei City (CN)

(72) Inventor: Xiaojie LI, Hefei City (CN)

(73) Assignee: CHANGXIN MEMORY TECHNOLOGIES, INC., Hefei City (CN)

(21) Appl. No.: 17/891,618

(22) Filed: Aug. 19, 2022

(30) Foreign Application Priority Data
Jun. 16, 2022 (CN) 202210686716.6

(51) Int. Cl. H01L 23/60; H01L 27/108

(52) U.S. Cl. CPC H01L 23/60; H01L 27/10805; H01L 27/1085; H01L 27/10873; H01L 27/10885; H01L 27/10891

(57) ABSTRACT

Provided is a semiconductor device, including an insulating layer, a transistor located on the insulating layer, and a conductive structure, in which the transistor includes: a source, a channel and a drain arranged in parallel, as well as a gate dielectric layer and a gate structure, in which the gate dielectric layer is located between the gate structure and the channel; the conductive structure covers one sidewall of the channel and is used for grounding; the gate structure is disposed around the other three sidewalls of the channel; and the gate structure and the conductive structure are isolated from each other.

### CROSS-REFERENCE TO RELATED APPLICATION

This application claims priority to Chinese Patent Application No. 202210686716.6, filed on Jun. 16, 2022, the disclosure of which is hereby incorporated by reference in its entirety.

### BACKGROUND

A transistor is an important element in an electronic circuit. It is a voltage-controlled switching device, in which the gate voltage controls the current flowing through the channel between the source and the drain.

The transistor can be used to form a memory. For example, in a dynamic random access memory (DRAM), a memory cell includes a transistor and a capacitor. The electrical property of the transistor has an important influence on the storage performance of the memory cell. Therefore, improving the electrical property of the transistor is an important way to improve the performance of the memory cell.

### SUMMARY

Embodiments of the disclosure relates to the technical field of semiconductor, in particular to a semiconductor device and a method for manufacturing the same.

According to the first aspect of embodiments of the disclosure, a semiconductor device is provided, which includes an insulating layer, a transistor located on the insulating layer, and a conductive structure.

The transistor includes a source, a channel and a drain arranged in parallel; and a gate dielectric layer and a gate structure, in which, the gate dielectric layer is located between the gate structure and the channel.

The conductive structure covers one sidewall of the channel and is used for grounding.

The gate structure is disposed around the other three sidewalls of the channel, and the gate structure and the conductive structure is isolated from each other.

According to the second aspect of embodiments of the disclosure, a method for manufacturing a semiconductor device is provided, which includes the following operations.

A substrate is provided.

A stacked structure covering the substrate is formed, which, includes a sacrificial layer and an active layer alternately stacked in turn along a direction perpendicular to the substrate, in which the active layer being used for forming a channel of a transistor.

The stacked structure is etched along the direction perpendicular to the substrate to form first trenches which extend in a first direction parallel to the substrate.

A source is formed at one end of the channel and a drain is formed at another end of the channel along the first direction.

The sacrificial layer is removed through the first trenches to form gaps.

The gaps and the first trenches are filled with an insulating material to form an insulating structure.

A second trench penetrating the insulating structure in the direction perpendicular to the substrate is formed to expose a first sidewall of the channel of a transistor, in which the second trench extend along the first direction.

A conductive structure covering the exposed first sidewall is formed through the second trench, in which the conductive structure is used for grounding.

A third trench penetrating the insulating structure in the direction perpendicular to the substrate is formed to expose another sidewall, opposite to the first sidewall, of the channel of the transistor.

Exposed ends of the insulating material are removed through the third trench to form first cavities extending in a second direction parallel to the substrate, in which the insulating material is provided between the first cavities and the conductive structure.

A gate dielectric layer and a gate structure are formed in sequence on the other three sidewalls of the channels through the third trench and the first cavities, in which the gate dielectric layer is located between the gate structure and the channel.

### BRIEF DESCRIPTION OF THE DRAWINGS

FIG. 1 is a schematic three-dimensional structural diagram of a semiconductor device according to an embodiment of the disclosure;

FIG. 2 is a schematic diagram of sidewalls of a channel in a semiconductor device according to an embodiment of the disclosure;

FIG. 3 is a schematic structural top view of a semiconductor device according to an embodiment of the disclosure;

FIG. 4 is a cross-sectional view along the AA line of the semiconductor device shown in FIG. 3;

FIG. 5 is a flow chat of a method for manufacturing a semiconductor device according to an embodiment of the disclosure; and

FIGS. 6A to 16B are schematic diagrams showing a process of manufacturing a semiconductor device according to an embodiment of the disclosure.

### DETAILED DESCRIPTION

The technical solution of the disclosure will be described in detail below with reference to the accompanying drawings and embodiments. Although exemplary embodiments of the present disclosure are shown in the drawings, it should be understood that the present disclosure may be implemented in various forms and should not be limited to the specific embodiments set forth herein. These embodiments are provided for the purpose that the disclosure will be more thoroughly understood and the scope of the disclosure will be fully conveyed to those skilled in the art.

The disclosure is described more specifically by way of example in the following paragraphs with reference to the accompanying drawings. The advantages and features of the disclosure will become clearer according to the following description and claims. It should be noted that, the drawings are all in very simplified form and use imprecise proportions merely for convenience and clarity to aid in illustrating the purpose of the embodiments of the disclosure.

It should be understood that the meanings of “on”, “over” and “above” in the disclosure should be interpreted in the widest manner so that “on” not only means its meaning of “on” something without intermediate features or layers therebetween (i.e. directly on something), but also includes “on” something with intermediate features or layers therebetween.

In an embodiment of the disclosure, terms “first”, “second”, “third” or the like are used to distinguish similar objects, and need not be used to describe a specific order or priority.

In an embodiment of the disclosure, the term “layer” refers to the material part of a region with a thickness. A layer may extend over the entirety of a lower or upper structure, or may have a range smaller than the range of the lower or upper structure. Further, a layer may be a region of a homogeneous or heterogeneous continuous structure whose thickness is less than the thickness of the continuous structure. For example, a layer may be located between the top and the bottom surfaces of a continuous structure, or a layer may be located between any pair of horizontal planes at the top surface and bottom surface of a continuous structure. A layer may extend horizontally, vertically, and/or along an inclined surface. A layer may include multiple sub-layers.

It should be noted that any technical solution described in embodiments of the disclosure can be arbitrarily combined without conflict.

Floating body effect (FBE) generally refers to the effect presented in a transistor made of silicon on insulator. According to whether the body region is depleted or not, silicon on insulator (SOI) devices can be divided into two types: partially depleted and fully depleted. In general, the top silicon film of a fully depleted SOI device is relatively thin, and the threshold voltage is not easy to control. Therefore, partially depleted SOI devices are widely used. However, since the body region of a partially depleted SOI device is not completely depleted, collisional ionization produces electron-hole pairs, and the generated electrons flow into the drain which is at a high potential, while the holes move to the body region which is at a low potential below the gate structure. However, since an insulating layer in the SOI device isolates the substrate from the body region, the surplus holes cannot be discharged through the substrate, resulting in the floating body effect in the transistor. For example, for a SOI NMOS device, channel electrons collide and ionize at the drain end of a transistor to generate electron-hole pairs, and the holes flow to the body region and accumulate in the body region, resulting in an increase in the potential of the body region, which leads to a decrease in the threshold voltage and an increase in the leakage current of the SOT NMOS device, thereby adversely affecting the circuit performance and reliability of the SOI NMOS device.

In view of this, the embodiments of the disclosure provide a semiconductor device.

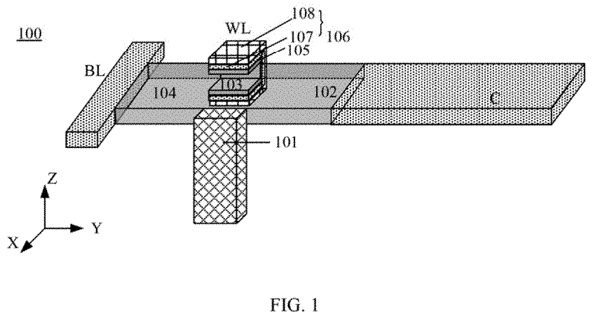

FIG. 1 is a schematic structural diagram of a semiconductor device according to an embodiment of the disclosure. Referring to FIG. 1, the semiconductor device 100 includes an insulating layer (not shown), a transistor located on the insulating layer, and a conductive structure 101.

The transistor includes a source 102, a channel 103 and a drain 104 arranged in parallel, and a gate dielectric layer 105 and a gate structure 106. The gate dielectric layer 105 is located between the gate structure 106 and the channel 103.

The conductive structure 101 covers one sidewall of the channel 103 and is used for grounding.

The gate structure 106 is disposed around the other three sidewalls of the channel 103, and the gate structure 106 and the conductive structure 101 are isolated from each other.

Here, the illustration is made to the semiconductor device 100 including a silicon-on-insulator (SOI) device. Specifically, the material of the insulating layer may include an oxide of silicon, for example, silicon dioxide.

In some embodiments, the transistor includes a planar type transistor or a vertical type transistor. For example, for a planar type transistor, the source, the channel, and the drain of the transistor are disposed in parallel in a direction parallel to the insulating layer. For a vertical type transistor, the source, the channel, and the drain of the transistor are arranged in parallel in a direction perpendicular to the insulating layer. Referring to FIG. 1, the illustration here is made to the transistor including a planar type transistor.

In an example, the source 102 and the drain 104 are P-type doped and the channel 103 is N-type doped. In another example, the source 102 and the drain 104 are N-type doped and the channel 103 is P-type doped. Here, the doping types of the source 102 and the drain 104 are the same and the doping concentrations of the source 102 and the drain 104 may be the same or different, which is not limited herein by the disclosure.

The gate structure 106 serves as a control gate of the transistor, and the gate dielectric layer 105 is located between the gate structure 106 and the channel 103 to isolate the gate structure 106 and the channel 103. Specifically, the material of the gate dielectric layer 105 may include silicon oxide, silicon nitride or other high dielectric constant (High-K) material. In some specific examples, the high dielectric constant material generally refers to a material with a dielectric constant higher than 3.9, and typically significantly higher than this value. A high dielectric constant material includes, but is not limited to, alumina (Al₂O₃), zirconia (ZrO), hafnium oxide (HfO₂), strontium titanate (SrTiO₃), or the like.

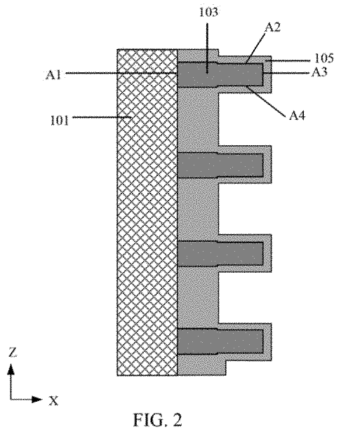

In an example, as shown in FIG. 2, the channel 103 includes four sidewalls A1, A2, A3 and A4; herein the sidewall A1 and the sidewall A3 are opposite sides, and the sidewall A2 and the sidewall A4 are opposite sides. Referring to FIG. 2, the conductive structure 101 covers one sidewall of the channel 103 (such as the sidewall A1 in FIG. 2), the gate structure 106 is disposed around the other three sidewalls of the channel 103. The other three sidewalls of the channel 103 refers to the sidewalls of the four sidewalls of the channel 103 other than the sidewall A1 coupled to the conductive structure 101, such as the sidewalls A2, A3, and A4 in FIG. 2. The conductive structure is used for grounding, thereby providing a discharge pathway for the charges generated by collisional ionization accumulated in the channel 103, reducing the influence of floating body effect on the transistor, and stabilizing the performance of the transistor.

Referring to FIG. 2, the conductive structure 101 is in direct contact with one sidewall A1 of the channel 103 and the conductive structure 101 is disposed covering the channel 103. Referring to FIGS. 1 and 2, the gate dielectric layer 105 is located between the gate structure 106 and the channel 103, the gate dielectric layer 105 is in direct contact with the other three sidewalls of the channel 103 (such as the sidewalls A2, A3, and A4 in FIG. 2), and the gate dielectric layer 105 is disposed covering the channel 103. The gate structure 106 is disposed covering the gate dielectric layer 105, thus the gate structure 106 is not in direct contact with the channel 103 and the gate structure 106 is disposed around the channel 103.

Referring to FIG. 1, the gate dielectric layer 105 and the channel 103 are provided between the gate structure 106 and the conductive structure 101, so that there is no direct contact between the gate structure 106 and the conductive structure 101 structurally, and no electrical contact structure is provided between the gate structure 106 and the conductive structure 101, and thus the gate structure 106 and the conductive structure 101 are isolated from each other.

In embodiments of the disclosure, regarding to the transistor located on the insulating layer, since the body region does not contact the substrate, the charges generated by collisional ionization cannot flow into the substrate and cannot be removed quickly, which leads to the floating body effect and the degradation of the performance of the transistor. The conductive structure is arranged to cover one sidewall of the channel of the transistor, and the conductive structure is used for grounding, thereby providing a discharge pathway for accumulated charges in the body region, releasing the charges accumulated in the channel generated by collisional ionization, reducing the influence of the floating body effect on the transistor, and stabilizing the performance of the transistor. In addition, the gate structure is arranged on the other three sidewalls around the channel, so that the control ability of the gate structure to the channel of the transistor is enhanced, and the performance of the transistor is further improved, thereby improving the storage performance of the memory cell and improving the storage performance of the memory.

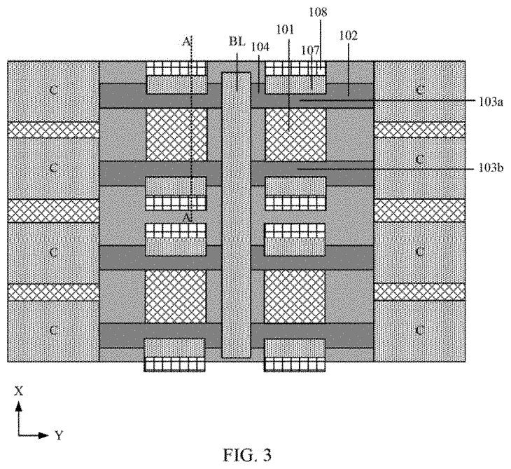

In some embodiments, referring to FIGS. 1 and 3, the source 102, the channel 103 and the drain 104 are disposed in parallel in the first direction. The first direction is parallel to the insulating layer.

The semiconductor device includes two transistors arranged in parallel along the second direction. The second direction is parallel to the insulating layer, and the second direction intersects with the first direction.

The conductive structure 101 is located between the channels of two transistors arranged in parallel along the second direction, and is electrically connected with both the channels 103 of the two transistors arranged in parallel along the second direction.

In some embodiments, the first direction intersects with the second direction, and the included angle between the first direction and the second direction may be any angle between 0 and 90 degrees.

For example, the first direction may be perpendicular to the second direction. Here and hereafter, for convenience of description, the first direction and the second direction in the embodiments of the disclosure represent two orthogonal directions parallel to the plane of the insulating layer and the third direction is a direction perpendicular to the plane of the insulating layer. Herein, the first direction is an extension direction of the channel 103 and the plane of the insulating layer can be understood as a plane parallel to the extension direction of the channel 103. The first direction may be denoted as the Y direction in the drawings, the second direction may be denoted as the X direction in the drawings, and the third direction may be denoted as the Z direction in the drawings.

In an embodiment, FIG. 1 illustrates that the source 102 is located at a first end of the channel 103 and the drain 104 is located at a second end of the channel 103. In another embodiment, the locations of the source 102 and the drain 104 may be interchangeable. For example, the drain 104 is at the first end of the channel 103 and the source 102 is at the second end of the channel 103. Here, the first direction is an extension direction of the channel 103 and the first end and the second end are opposite ends of the channel 103 in the first direction (e.g. the Y direction in FIG. 1) respectively.

In the embodiments of the disclosure, Referring to FIG. 3, a first transistor and a second transistor are arranged in parallel in the second direction, in which a conductive structure 101 is provided between the channel 103a of the first transistor and the channel 103b of the second transistor. That is, the conductive structure 101 is electrically connected to both the channels 103a and 103b of the two transistors arranged in parallel in the second direction, and the charges generated by collisional ionization accumulated in the channels of both the two transistors is discharged through the same conductive structure 101, to reduce the influence of floating body effect on the transistors and stabilize the performance of the transistors. In addition, the channels of the two transistors electrically connected to the same conductive structure 101, compared with one transistor provided with one conductive structure, the embodiments of the disclosure can improve the utilization of the conductive structure, and reduce the number of the conductive structures needed to be provided in the whole memory device, and further reduce the space occupied by the conductive structure 101, which is beneficial to further improve the integration of the memory.

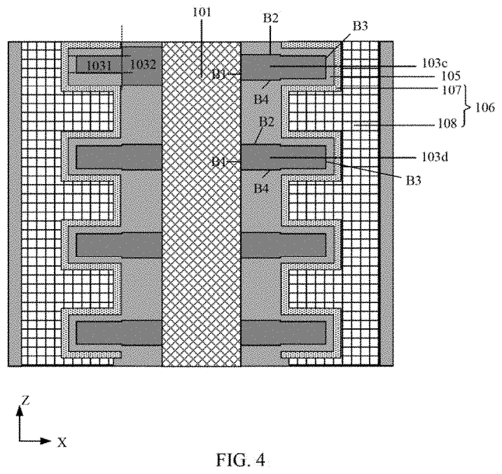

In some embodiments, referring to FIGS. 1 and 4, the source 102, the channel 103 and the drain 104 are disposed in parallel in the first direction which is parallel to the insulating layer.

The semiconductor device includes two transistors arranged in parallel along the third direction; in which the third direction is perpendicular to the insulating layer.

The conductive structure 101 is located on the same side of the channels of the two transistors arranged in parallel along the third direction, and is electrically connected with both the channels 103 of the two transistors arranged in parallel along the second direction which is parallel to the insulating layer.

Referring to FIG. 4, a third transistor and a fourth transistor are provided in parallel in the third direction and the channel 103c of the third transistor and the channel 103d of the fourth transistor include four sidewalls B1, B2, B3 and B4, respectively. The sidewalls of the channel 103c of the third transistor and the channel 103d of the fourth transistor at the same side (sidewall B1 as shown in FIG. 4) are in contact with the conductive structure 101. That is, the conductive structure 101 is located on the same side of the channels 103 of the two transistors arranged in parallel in the third direction (Z direction), and the charges generated by collisional ionization accumulated in the channels 103 of the two transistors arranged in parallel in the third direction (Z direction) are discharged through the conductive structure 101. In addition, the channels 103 of the two transistors arranged in parallel in the third direction (Z direction) are electrically connected to the same conductive structure 101. The conductive structure 101 may also be located on the same side of the channels 103 of a plurality of the transistors arranged in parallel in the third direction (Z direction), which is not limited by the disclosure.

In the embodiments of the disclosure, the charges generated by collisional ionization accumulated in the channels of the two transistors arranged in parallel in the third direction is discharged through the same conductive structure 101, to reduce the influence of floating body effect on the transistors and stabilize the performance of the transistors. Compared with one transistor provided with one conductive structure, the embodiments of the disclosure can improve the utilization of the conductive structure, and reduce the number of the conductive structures needed to be provided in the whole memory device, and further reduce the space occupied by the conductive structure 101, which is beneficial to further improve the integration of the memory.

In some embodiments, referring to FIG. 1, the gate structure 106 includes a connecting layer 107 and a conductive layer 108; in which, the connecting layer 107 is located between the gate dielectric layer 105 and the conductive layer 108, and is used for increasing the adhesion between the conductive layer 108 and the gate dielectric layer 105.

The gate structure 106 serves as a control gate of the transistor, which controls the turn-on or turn-off of the transistor connected to the gate structure 106 by controlling a voltage applied to the gate structure 106. Here, the gate structure 106 is described as including a two-layer structure (a connecting layer 107 and a conductive layer 108).

Specifically, the material of the conductive layer 108 may include a metal (e.g. tantalum, titanium, molybdenum, tungsten, platinum, aluminum, hafnium, ruthenium, etc.), a metal silicide (e.g. titanium silicide, cobalt silicide, nickel silicide, tantalum silicide, etc.), or a conductive material such as doped polysilicon. The material of the connecting layer 107 includes a metal nitride, such as titanium nitride, tantalum nitride or the like.

In embodiments of the disclosure, a connecting layer 107 is arranged between the gate dielectric layer 105 and the conductive layer 108 to increase the adhesion between the conductive layer 108 and the gate dielectric layer 105, so as to enhance or improve the stability of the gate structure 106, further improve the control ability of the gate structure 106 to the transistor, which is beneficial to improving the operation stability and reliability of the memory.

In some embodiments, referring to FIG. 4, along the second direction parallel to the insulating layer, the channel 103 includes a first part and a second part, in which in a plane parallel to the insulating layer, the projection of the first part is located in the projection of the gate structure 106, and the projection of the second part is located outside the projection of the gate structure 106.

In the third direction perpendicular to the insulating layer, the dimension of the first part is smaller than the dimension of the second part.

Referring to FIG. 4, the channel 103 includes a first part 1031 and a second part 1032. It could be understood that when forming the channel 103, the material constituting the channel 103 can be divided into a first material part and a second material part which is flush with the first material part in the X direction, and the first material part and the second material part have the same size in the third direction (Z direction) perpendicular to the insulating layer. It should be noted that, the first material part is used to form the first part of the channel and the second material part is used to form the second part of the channel. The channel can be formed by an operation, such as doping the first material part and the second material part.

In practice, the gate dielectric layer 105 may be formed by oxidation, for example, the material of the channel 103 includes silicon, the material of the gate dielectric layer 105 includes silicon dioxide, and the gate dielectric layer 105 is formed by in-situ silicon oxidation, in the first material part of the channel 103, a part of the silicon layer is oxidized to generate silicon dioxide to form the gate dielectric layer 105, which is a continuous structure surrounding the first part of the channel 103.

In the process of forming the gate dielectric layer 105 by oxidizing the material of the channel, a part of silicon of the first material part of the channel 103 is consumed and then a first portion 1031 is formed. It should be noted that after the gate dielectric layer 105 is formed, the remaining first material part of the channel 103 forms the first part 1031.

For example, referring to FIG. 4, in the Z direction, the total thickness of the gate dielectric layer 105 and the first part 1031 may be substantially equal to the thickness of the second part 1032; and in the X direction, the total thickness of the gate dielectric layer 105 and the first part 1031 may be substantially equal to the thickness of the second part 1032.

Referring to FIG. 4, after the gate dielectric layer 105 is formed, the first part 1031 and the second part 1032 of the channel 103 are not flush in the X direction. That is, in the third direction (Z direction) perpendicular to the insulating layer, the dimension of the first part 1031 is smaller than the dimension of the second part 1032.

In another example, the channel 103 includes a first part 1031 and a second part 1032. It could be understood that when the gate dielectric layer 105 is formed by deposition, the gate dielectric layer 105 covering the channel 103 may be formed by one or more deposition processes including, but not limited to, physical vapor deposition (PVD), chemical vapor deposition (CVD), atomic layer deposition (ALD), or any combination thereof. After the gate dielectric layer 105 is formed, the dimension of the first part of the channel 103 is equal to the dimension of the second part in the third direction (Z direction) perpendicular to the insulating layer (not shown).

In some embodiments, the transistors are N-type.

The material of the conductive structure 101 includes a P-type semiconductor material.

It is easy to understand that, for a partially depleted SOI NMOS device, the channel electrons get enough energy at the drain under a sufficiently high drain voltage, and electron-hole pairs generate by collisional ionization. The generated electrons flow into the drain which is at a high potential, while the holes move to the body region which is at a low potential below the gate structure. However, due to the isolation of the insulating layer in the SOI device, the surplus holes cannot flow into the substrate. In addition, due to the high potential barrier between the source region and the body region, the surplus holes cannot recombine with the electrons in the source region, which causes the surplus holes to accumulate in the body region and elevate the potential of the body region, so that the threshold voltage of the SOI NMOS device decrease and the leakage current increase, which adversely affects the performance and reliability of the SOI NMOS device and the circuit.

Specifically, the transistor is N-type, the material of the conductive structure 101 includes polysilicon and the composition material of the conductive structure 101 may also include P-doped polysilicon.

In embodiments of the disclosure, in order to solve the problem of the floating body effect in a SOI NMOS device, when the transistor is N-type, a P-type conductive structure is arranged to cover one sidewall of the channel of the N-type transistor, and the conductive structure is used for grounding, thereby providing a discharge pathway for accumulated charges in the body region, releasing the charges accumulated in the channel generated by collisional ionization, reducing the influence of the floating body effect on the N-type transistor, and stabilizing the performance of the transistor. In addition, the gate structure is arranged on the other three sidewalls around the channel, so that the control ability of the gate structure to the channel of the transistor is enhanced, and the performance of the transistor is further improved, thereby improving the storage performance of the memory cell and improving the storage performance of the memory.

In some embodiments, the semiconductor device includes: a memory cell array, a plurality of word lines and a plurality of bit lines.

The memory cell array includes a plurality of memory cell rows spaced apart from each other along a second direction and a plurality of memory cell columns spaced apart from each other along a third direction. The second direction is parallel to the insulating layer, the third direction is perpendicular to the insulating layer. Each memory cell row includes a plurality of memory cells arranged in parallel along the third direction, and each memory cell column includes a plurality of memory cells arranged in parallel along the second direction. Each memory cell includes the transistor.

The plurality of word lines are spaced apart from each other along the second direction, and are respectively coupled to the gate structures of a plurality of the transistors included in the memory cell rows.

The plurality of bit lines are spaced apart away each other along the third direction, and are respectively coupled to the drains of a plurality of the transistors included in the memory cell columns.

In practice, referring to FIG. 1, a word line WL is connected to the gate structure of the transistor in a memory cell, and the word line WL is used to provide a word line voltage and to control the turn-on or turn-off of the channel in the transistor through the word line voltage. A bit line BL extending in the second direction (X direction) is connected to the drain of the transistor, and the bit line BL is used for performing a read or write operation on the memory cell when the transistor is turned on.

In practice, the material of the word line WL and the bit line BL includes, but is not limited to tungsten, cobalt, copper, aluminum, polysilicon, doped silicon, silicide, or any combination thereof.

In embodiments of the disclosure, the semiconductor device includes a memory cell array. The memory cell array includes a plurality of memory cells, and the memory cells include the transistors. A conductive structure is arranged to cover one sidewall of the channel of the transistor, and the conductive structure is used for grounding, thereby releasing the charge accumulated in the channel generated by collisional ionization, reducing the influence of the floating body effect on the transistor, and stabilizing the performance of the transistor, so that the storage performance of the memory cell can be improved, and the storage performance of the memory can be further improved.

In some embodiments, referring to FIG. 1, the memory cell further include a capacitor C, the capacitor C includes a first electrode plate, an interelectrode dielectric layer and a second electrode plate, in which the first electrode plate is in contact with the source, and the interelectrode dielectric layer electrically isolates the first electrode plate and the second electrode plate.

Here, the dynamic random access memory (DRAM) is described as an example. Generally, the memory cell of the DRAM includes the memory cell architecture with one transistor T and one capacitor C (1T1C), and the capacitor C is used to store the written data.

It could be understood that, in the 1T1C architecture, the locations of the source and the drain can be interchanged. When the capacitor C in the memory cell is connected to the source of the transistor T, the bit line is connected to the drain of the transistor T. Alternatively, when the capacitor C in the memory cell is connected to the drain of the transistor T, the bit line is connected to the source of the transistor T. This is not limited by the disclosure.

In an example, the first electrode plate is in contact with the source, the interelectrode dielectric layer electrically isolates the first electrode plate from the second electrode plate, and the second electrode plate is coupled to a reference voltage end. The reference voltage may be a ground voltage or may include other voltages. In another example, the second electrode plate is in contact with the source, the interelectrode dielectric layer electrically isolates the first electrode plate from the second electrode plate, and the first electrode plate is coupled to the reference voltage end.

It should be noted that, only common memories are exemplified herein, and the protection scope of the disclosure is not limited thereto, and any memory including transistors provided by embodiments of the disclosure falls within the protection scope of the disclosure.

In some embodiments, the transistor may also be applied to the peripheral circuit of a memory, where the transistor may be coupled to a memory cell of the memory for controlling operation of the memory cell.

In some embodiments, for a DRAM memory, the memory cell of the DRAM includes a memory cell architecture with one transistor T and one capacitor C, the capacitor C is used for storing the written data. A conductive structure is arranged to cover one sidewall of the channel of the transistor T, and the conductive structure is used for grounding, thereby releasing the charges accumulated in the channel generated by collisional ionization, reducing the influence of the floating body effect on the transistor, and stabilizing the performance of the transistor, so that the storage performance of the memory cell with 1T1C architecture can be improved, and the storage performance of the DRAM memory can be further improved.

In some embodiments, the shape of the first electrode plate includes a cylindrical shape, and an axial direction of the first electrode plate with a cylindrical shape is parallel to the first direction. The first direction is parallel to the insulating layer.

The shape of the second electrode plate includes a cylindrical shape, and an axial direction of the second electrode plate with a cylindrical shape is parallel to the first direction. The radius of the second electrode plate with a cylindrical shape is smaller than the radius of the first electrode plate with a cylindrical shape.

In practice, the capacitor includes a second electrode plate with a cylindrical shape, an interelectrode dielectric layer covering the sidewall and the bottom of the second electrode plate, and a first electrode plate with a cylindrical shape covering the interelectrode dielectric layer.

In another embodiment, the shape of the capacitor further includes a planar shape, and the capacitor with a planar shape includes a first electrode plate, an interelectrode dielectric layer and a second electrode plate stacked in sequence, in which the first electrode plate, the interelectrode dielectric layer and the second electrode plate are parallel to each other. It could be understood that when the relative area of the first electrode plate and the second electrode plate is constant, the space occupied by the capacitor with a cylindrical shape is smaller than that of the capacitor with a planar shape, which is beneficial to further improve the integration of the memory. On the basis of this, in practice, capacitors with a cylindrical shape are used.

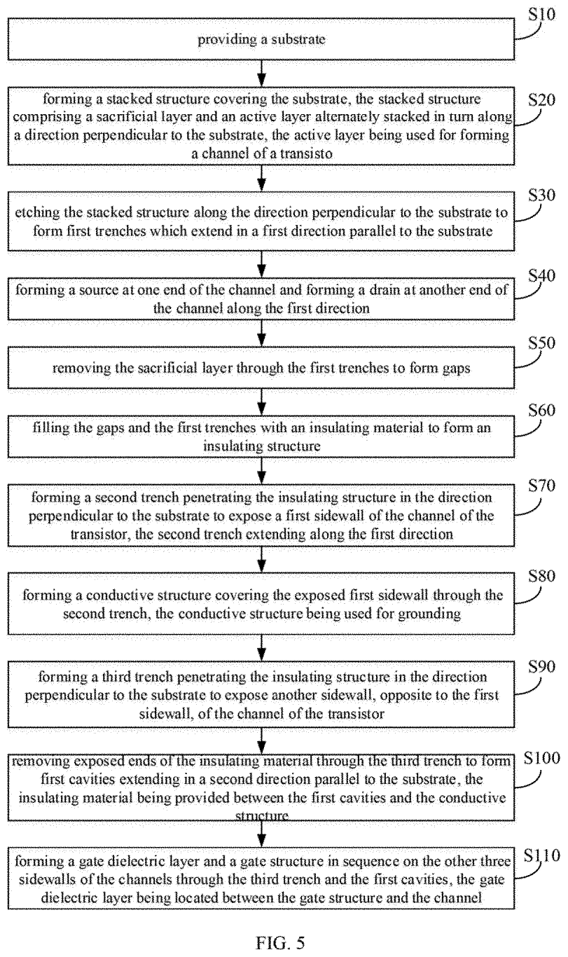

Embodiments of the disclosure also provide a method for manufacturing a semiconductor device. FIG. 5 is a flow chat of the manufacturing method of a semiconductor device provided by an embodiment of the disclosure. As shown in FIG. 5, the manufacturing method includes the following operations.

In S10, a substrate is provided;

In S20, a stacked structure covering the substrate is formed, in which, the stacked structure includes a sacrificial layer and an active layer alternately stacked in turn along a direction perpendicular to the substrate, and the active layer is used for forming a channel of a transistor.

In S30, the stacked structure is etched along the direction perpendicular to the substrate to form first trenches, in which the first trenches extend in a first direction parallel to the substrate.

In S40, a source is formed at one end of the channel and a drain is formed at another end of the channel along the first direction.

In S50, the sacrificial layer is removed through the first trenches to form gaps.

In S60, the gaps and the first trenches are filled with an insulating material to form an insulating structure.

In S70, a second trench penetrating the insulating structure in the direction perpendicular to the substrate is formed to expose a first sidewall of the channel of the transistor, in which the second trench extend along the first direction.

In S80, a conductive structure covering the exposed first sidewall is formed through the second trench, in which the conductive structure is used for grounding.

In S90, a third trench penetrating the insulating structure in the direction perpendicular to the substrate is formed to expose another sidewall of the channel of the transistors opposite to the first sidewall.

In S100, exposed ends of the insulating material are removed through the third trench to form first cavities extending in a second direction parallel to the substrate, in which the insulating material is provided between the first cavities and the conductive structure.

In S110, a gate dielectric layer and a gate structure are formed in sequence on the other three sidewalls of the channels through the third trench and the first cavities, in which the gate dielectric layer is located between the gate structure and the channel.

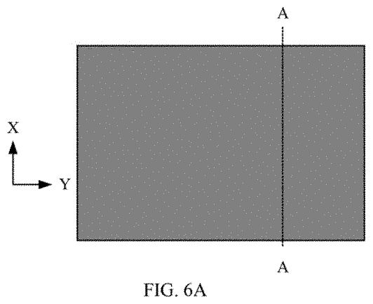

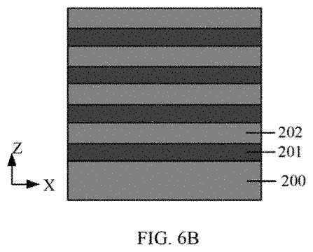

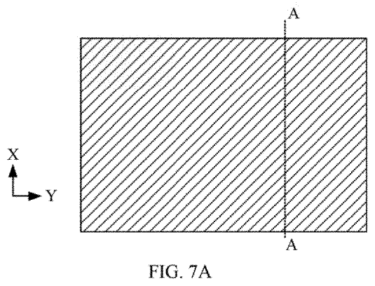

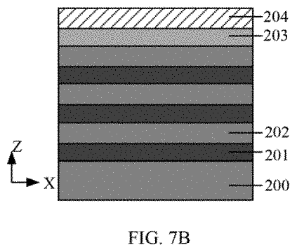

FIGS. 6A to 16B are schematic diagrams showing a process of manufacturing a semiconductor device in embodiments of the disclosure, and the method for manufacturing a semiconductor device provided by the embodiments of the disclosure will be described below in combination with FIGS. 5, 6A to 16B. It should be noted that, FIG. 6B is a cross-sectional view of the semiconductor device shown in FIG. 6A along line A-A; FIG. 7B is a cross-sectional view of the semiconductor device shown in FIG. 7A along line A-A and so on.

Performing S10, a substrate 200 is provided, the material of which may include silicon (Si), germanium (Ge), silicon germanium (SiGe), or the like, and the material of the substrate 200 may also be silicon-on-insulator (SOI) or germanium-on-insulator (GOI).

Referring to FIGS. 6A and 6B, performing S20, the material of the sacrificial layers 201 may include silicon germanium (SiGe) or the like, and the material of the active layers 202 may include silicon (Si), germanium (Ge) or the like. The active layers 102 may be doped with certain impurity ions as required and the impurity ions may be N-type impurity ions or P-type impurity ions.

In practice, the sacrificial layers 201 and the active layers 202 can be sequentially and alternately deposited on the substrate 200 by epitaxial growth. The stacked structure may also be formed by one or more deposition processes including, but not limited to physical vapor deposition, chemical vapor deposition, atomic layer deposition, or any combination thereof.

In an embodiment, an active layer 202 may be optionally formed on the substrate 200 according to the actual requirements of the device. In another embodiment, the active layer 202 may also be formed on other functional thin film layers.

In some embodiments, as shown in FIGS. 7A and 7B, a dielectric layer 203 and a mask layer 204 are also sequentially stacked on the stacked structure, in which the material of the dielectric layer 203 includes oxide, such as silicon oxide. The material of the mask layer 204 may include silicon nitride. The dielectric layer 203 and the mask layer 204 may also be formed by one or more deposition processes including, but not limited to physical vapor deposition, chemical vapor deposition, atomic layer deposition, or any combination thereof.

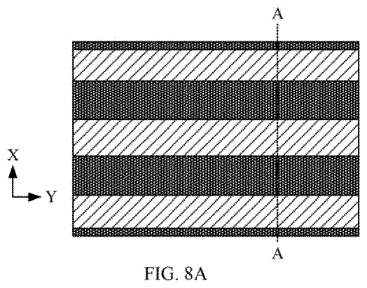

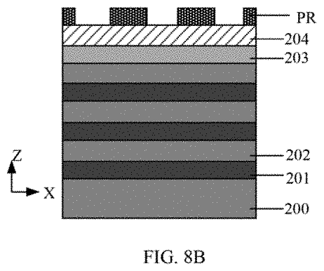

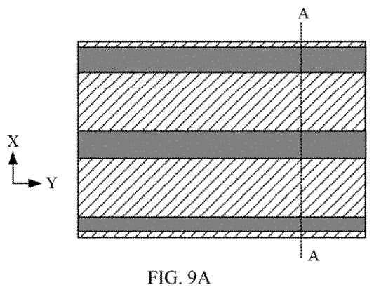

In some embodiments, referring to FIGS. 8A and 8B, a photoresist PR is formed on the surface of the mask layer 204 and the photoresist PR is patterned for etching to form first trenches H1 based on openings exposed by the photoresist PR.

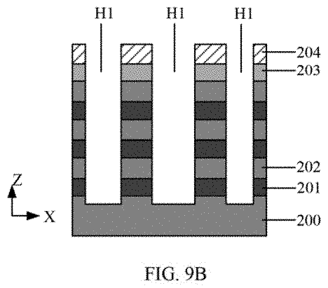

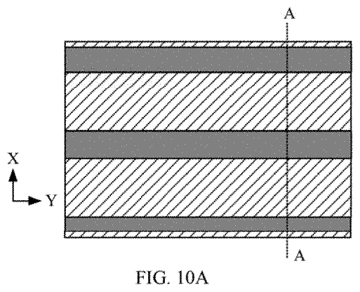

Referring to FIGS. 9A and 9B, performing S30, in this embodiment, the first trenches H1 extend into the substrate 200 penetrating through the mask layer 204, the dielectric layer 203 and the stacked structure.

In practice, the first trenches H1 can be formed by dry etching, such as ion milling etching, plasma etching, reactive ion etching, laser ablation or the like. After the first trenches H1 are formed, the photoresist PR on the surface of the mask layer 204 is removed.

In some embodiments, performing S40, a source and a drain (not shown) are formed at opposite ends of each channel respectively. In an example, the source and the drain are P-type doped and the channel is N-type doped. In another example, the source and the drain are N-type doped and the channel is P-type doped. Here, the doping types of the source and the drain are the same and the doping concentrations of the source and the drain may be the same or different, which is not limited herein by the disclosure.

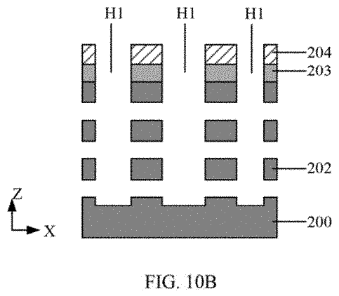

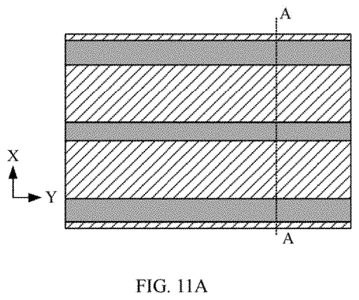

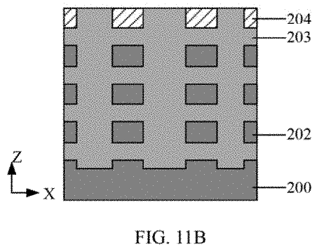

Referring to FIGS. 11A and 10B, performing S50, the sacrificial layers 201 may be removed by wet etching, in which the etchant of the wet etching process etch the sacrificial layers 201 through the first trenches H1 to form gaps. The etchant used in the wet etching process includes hydrogen peroxide solution.

Referring to FIGS. 11A and 11B, performing S60, the insulating material may be the same as the material of the dielectric layer 203, and the insulating material includes an oxide of silicon, such as silicon dioxide. The insulating structure may be formed by one or more deposition processes including, but not limited to physical vapor deposition, chemical vapor deposition, atomic layer deposition, or any combination thereof.

In some embodiments, after the insulating material is deposited, a chemical mechanical polishing is performed on the insulating structure, so that the surface of the insulating structure is flush with the surface of the mask layer 204.

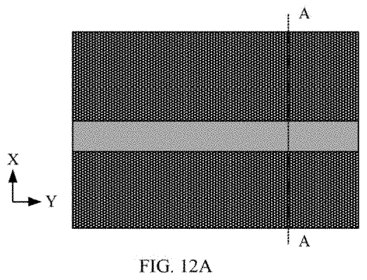

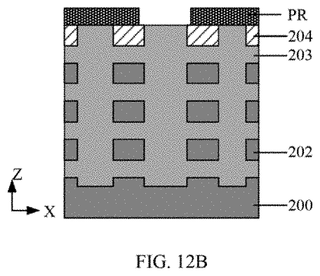

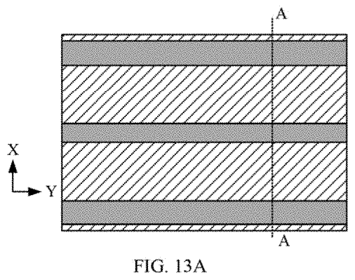

Referring to FIGS. 12A and 12B, a photoresist PR is formed on the surface of the mask layer 204 and the photoresist PR is patterned for etching to form a second trench H2 based on the opening exposed by the photoresist PR.

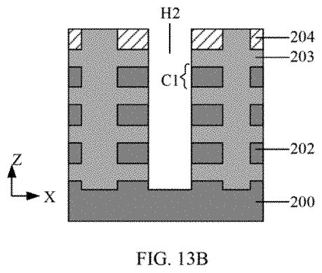

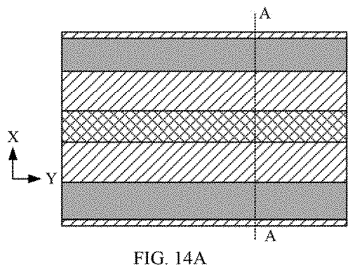

Referring to FIGS. 13A and 13B, performing S70, in this embodiment, the second trench H2 extend into the substrate 200 penetrating through the mask layer 204, the dielectric layer 203 and the stacked structure. As shown in FIG. 13B, the second trench H2 exposes the first sidewall C1 of the channels.

In practice, the second trench H2 can be formed by dry etching, such as ion milling etching, plasma etching, reactive ion etching, laser ablation or the like. After the second trench H2 is formed, the photoresist PR on the surface of the mask layer 204 is removed.

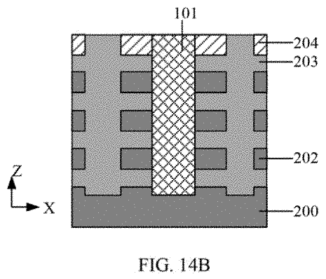

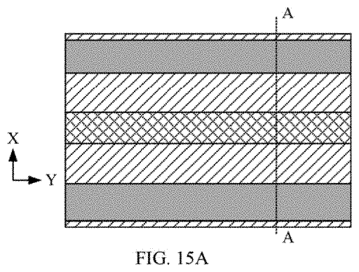

Referring to FIGS. 14A and 14B, S80 is performed. The conductive structure 101 may be formed by one or more deposition processes including, but not limited to physical vapor deposition, chemical vapor deposition, atomic layer deposition, or any combination thereof.

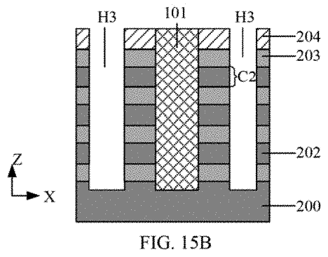

Referring to FIGS. 15A and 15B, performing S90, in this embodiment, third trenches H2 extend into the substrate 200 penetrating through the mask layer 204, the dielectric layer 203 and the stacked structure.

In practice, the third trenches H3 can be formed by dry etching, such as ion milling etching, plasma etching, reactive ion etching, laser ablation or the like. The third trenches H3 are formed to expose another sidewall (sidewall C2 shown in FIG. 15B) opposite to the first sidewall of the channel of each of the transistors.

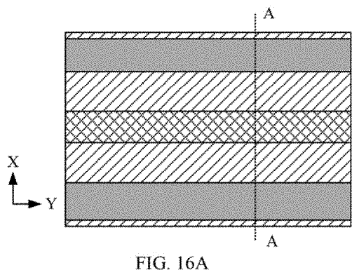

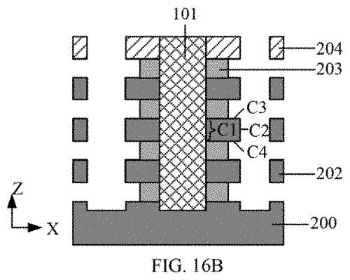

Referring to FIGS. 16A and 16B, performing S100, the exposed ends of the insulating material may be removed by wet etching. The etchant of the wet etching process etch part of the insulating material through the third trenches 113 to form the first cavities.

In an example, referring to FIG. 16B, the conductive structure 101 covers one sidewall of each channel (sidewall C1 shown in FIG. 168), and the gate structure is disposed around the other three sidewalls of each channel (sidewalls C2, C3, and C4 shown in FIG. 16B). The gate structures and the conductive structure 101 are isolated from each other. The conductive structure 101 is used for grounding, thereby providing a discharge pathway for accumulated charges generated by collisional ionization, reducing the influence of the floating body effect on the transistor, and stabilizing the performance of the transistor.

Performing S110, the process of forming the gate dielectric layers may include forming the gate dielectric layers by oxidation, or forming the gate dielectric layers by deposition. After the gate dielectric layers are formed, the gate structures respectively covering the gate dielectric layers are formed by deposition. The oxidation process includes, but is not limited to an in-situ oxidation process. The deposition process includes, but is not limited to physical vapor deposition, chemical vapor deposition, atomic layer deposition, or any combination thereof.

It should be understood that, the operations shown in S10 to S110 are not necessarily performed precisely in order, but rather various operations may be processed in any order or simultaneously. In addition, other operations can also be added to these processes.

In embodiments of the disclosure, for the transistors located on the insulating layer, since the body region is in a state of not contacting the substrate, the charges generated by collisional ionization cannot be removed quickly, which leads to the floating body effect and the degradation of the performance of the transistor. A conductive structure is arranged to cover one sidewall of the channel of each transistor, and the conductive structure is used for grounding, thereby providing a discharge pathway for accumulated charges in the body region, releasing the charge accumulated in the channel generated by collisional ionization, reducing the influence of the floating body effect on the transistor, and stabilizing the performance of the transistor. In addition, each gate structure is arranged on the other three sidewalls around each channel, so that the control ability of the gate structures to the channels of the transistors is enhanced, and the performance of the transistors is further improved.

In some embodiments, referring to FIGS. 13A and 13B, forming the conductive structure 101 covering the exposed first sidewalls through the second trench H2 includes the following operations.

A semiconductor filling layer is formed in the second trench H2.

A doping process is performed on the semiconductor filling layer to form the conductive structure 101.

Referring to FIGS. 13A and 13B, in this embodiment, the second trench H2 extend into the substrate 20) penetrating through the mask layer 204, the dielectric layer 203 and the stacked structure. As shown in FIG. 13B, the second trench H2 exposes the first sidewalls C1 of the channels.

In practice, the second trench H2 can be formed by dry etching, such as ion milling etching, plasma etching, reactive ion etching, laser ablation or the like. After the second trench H2 is formed, the photoresist PR on the surface of the mask layer 204 is removed.

Here, the conductivity type of the conductive structure 101 is different from the type of the transistors. For example, when the transistors are N-type, the type of the conductive structure 101 is P-type. For example when the transistors are P-type, the type of the conductive structure 101 is N-type.

Specifically, the transistors are N-type, the material of the conductive structure 101 includes polysilicon. The material of the conductive structure 101 may also include P-doped polysilicon.

In embodiments of the disclosure, a P-type conductive structure is arranged to cover one sidewall of the channel of each N-type transistor, and the conductive structure is used for grounding, thereby providing a discharge pathway for accumulated charges in the body region, releasing the charges accumulated in the channel generated by collisional ionization, reducing the influence of the floating body effect on the N-type transistor, and stabilizing the performance of the transistor. In addition, the gate structure is arranged on the other three sidewalls around each channel, so that the control ability of the gate structure to the channel of the transistor is enhanced, and the performance of the transistor is further improved, thereby improving the storage performance of the memory cell and improving the storage performance of the memory.

In some embodiments, referring to FIGS. 16A and 16B, forming the gate dielectric layer and the gate structure in sequence on the other three sidewalls of the channels through the third trenches H3 and the first cavities includes the following operations.

An oxidation treatment is performed on the sidewalls of each channel exposed by the third trenches and the first cavities to form the gate dielectric layers.

The gate structures covering the gate dielectric layers are formed. The each of the channels includes a first part and a second part in the second direction parallel to the substrate, the gate dielectric layer covering the first part of the channel. In a plane parallel to the substrate, a projection of the first part is located in a projection of the gate structure, and a projection of the second part is located outside the projection of the gate structure; and in a third direction perpendicular to the substrate, the dimension of the first part is smaller than the dimension of the second part.

The process of forming the gate dielectric layers may include forming the gate dielectric layers by oxidation, or forming the gate dielectric layers by deposition. After the gate dielectric layers are formed, the gate structures covering the gate dielectric layers are formed by deposition. The oxidation process includes, but is not limited to an in-situ oxidation process. The deposition process includes, but is not limited to physical vapor deposition, chemical vapor deposition, atomic layer deposition, or any combination thereof.

Specifically, the other three exposed sidewalls of each channel (i.e. the exposed sidewalls C3, C4, and C5 as shown in FIG. 16B) may be oxidized in-situ in oxygen atmosphere by heating or pressurizing to form a gate dielectric layer.

In the embodiments of the disclosure, when the gate dielectric layers are formed by oxidation, a part of the first part of each channel is consumed by oxidation, and the dimension of the first part is smaller than that of the second part in the third direction (Z direction) perpendicular to the substrate 100.

In another example, when the gate dielectric layers 105 are formed by deposition, the dimension of the first part of each channel is equal to the dimension (not shown) of the second part in the third direction (Z direction) perpendicular to the substrate.

In some embodiments, each gate structure includes a connecting layer and a conductive layer. The connecting layer is located between the gate dielectric layer and the conductive layer.

After the gate dielectric layers are formed, forming the gate structures respectively covering the gate dielectric layers includes the following operations.

Connecting layers respectively covering the gate dielectric layers are formed.

The conductive layers respectively covering the connecting layers are formed. The connecting layers are used for increasing the adhesion between the conductive layers and the gate dielectric layers.

Referring to FIG. 1, the gate structure 106 includes the connecting layer 107 and the conductive layer 108, in which the connecting layer 107 is located between the gate dielectric layer 105 and the conductive layer 106. The gate structure 106 serves as a control gate of the transistor, which controls the turn-on or turn-off of the transistor connected to the gate structure 106 by controlling a voltage applied to the gate structure 106. Here, the gate structure 106 is described as including a two-layer structure (a connecting layer 107 and a conductive layer 108).

Specifically, the material of the conductive layer 108 may include a metal (e.g. tantalum, titanium, molybdenum, tungsten, platinum, aluminum, hafnium, ruthenium, etc.), a metal silicide (e.g. titanium silicide, cobalt silicide, nickel silicide, tantalum silicide, etc.), or a conductive material such as doped polysilicon. The material of the connecting layer 107 includes metal nitride, such as titanium nitride, tantalum nitride or the like.

In embodiments of the disclosure, by forming the connecting layer 107 covering the gate dielectric layer 105, and forming the conductive layer 108 covering the connecting layer 107, the connecting layer 107 is used to increase the adhesion between the conductive layer 108 and the gate dielectric layer 105, so as to enhance or improve the stability of the gate structure 106, further improve the control ability of the gate structure 106 to the transistor, which is beneficial to improving the operation stability and reliability of the memory.

In some embodiments, the material of the sacrificial layers 201 includes silicon germanium, and the material of the active layers 202 includes silicon.

The material of the sacrificial layers 201 may include silicon germanium (SiGe) or the like, and the material of the active layers 202 may include silicon (Si), germanium (Ge) or the like. The active layers 202 may be doped with certain impurity ions as required and the impurity ions may be N-type impurity ions or P-type impurity ions.

In the embodiments of the disclosure, the material of the sacrificial layers 201 includes silicon germanium, the material of the active layers 202 includes silicon, and the stacked structure includes a stacked layer of Si and SiGe. Since the etching selective ratio of Si and SiGe is relatively large, the sacrificial layers 201 (SiGe) can be easily removed due to the etching selection in the subsequent process for removing the sacrificial layers.

In some embodiments, the manufacturing method includes the following operations.

A memory cell array is formed, in which the memory cell array includes a plurality of memory cell rows spaced apart from each other along the second direction and a plurality of memory cell columns spaced apart from each other along a third direction, where the second direction is parallel to the substrate, and the third direction is perpendicular to the substrate, in which each memory cell row includes a plurality of memory cells arranged in parallel along the third direction, each memory cell column includes a plurality of memory cells arranged in parallel along the second direction, and each memory cell including the transistor.

A plurality of word lines spaced apart from each other along the second direction are formed, in which the word lines are respectively coupled to the gate structures of a plurality of the transistors included in the memory cell rows.

A plurality of bit lines spaced apart from each other along the third direction are formed, in which the bit lines are respectively coupled to the drains of a plurality of the transistors included in the memory cell columns.

In practice, in order to increase the integration degree of a memory, a multi-layer memory cell array is formed, which includes a plurality of memory cell rows and a plurality of memory cell columns. The word line is connected to the gate structures of the transistors in a memory cell row, and the word line is used to provide a word line voltage and to control the turn-on or turn-off of the channels in the transistors through the word line voltage. The bit line is connected to the drains of the transistors in a memory cell column, and the bit line is used for performing a reading or writing operation on the memory cells when the transistors are turned on.

In practice, the material of the word line and the bit line includes, but is not limited to tungsten, cobalt, copper, aluminum, polysilicon, doped silicon, silicide or any combination thereof.

In the embodiments of the disclosure, the semiconductor device formed with a multi-layer memory cell array can improve the integration degree of the memory. In addition, the memory cell array includes a plurality of memory cells, and each memory cell includes a transistor. A conductive structure is arranged to cover one sidewall of the channel of the transistor, and the conductive structure is used for grounding, thereby releasing the charges accumulated in the channel generated by collisional ionization, reducing the influence of the floating body effect on the transistor, and stabilizing the performance of the transistor, so that the storage performance of the memory cell can be improved, and the storage performance of the memory can be further improved.

In some embodiments, forming the memory cell array includes the following operation.

A capacitor coupled to the transistor is formed, in which the capacitor includes a first electrode plate, an interelectrode dielectric layer and a second electrode plate, in which the first electrode plate is in contact with the source of the transistor, and the interelectrode dielectric layer electrically isolates the first electrode plate and the second electrode plate.

Here, the dynamic random access memory (DRAM) is described as an example. Generally, a memory cell of the DRAM includes memory cell architecture with one transistor T and one capacitor C (1T1C), and the capacitor C is used to store the written data.

A capacitor coupled to the transistor is formed. The process of forming the capacitor includes sequentially forming a first electrode plate, an interelectrode dielectric layer, and a second electrode plate. In an example, the first electrode plate is in contact with the source, the interelectrode dielectric layer electrically isolates the first electrode plate from the second electrode plate, and the second electrode plate is coupled to a reference voltage end, or a ground voltage or other voltages. In another example, the second electrode plate is in contact with the source, the interelectrode dielectric layer electrically isolates the first electrode plate from the second electrode plate, and the first electrode plate is coupled to the reference voltage end.

In some embodiments, for a DRAM memory, a memory cell of the DRAM includes a memory cell architecture with one transistor T and one capacitor C, the capacitor C is used for storing the written data. A conductive structure is arranged to cover one sidewall of the channel of the transistor T, and the conductive structure is used for grounding, thereby releasing the charges accumulated in the channel generated by collisional ionization, reducing the influence of the floating body effect on the transistor, and stabilizing the performance of the transistor, so that the storage performance of the memory cell with 1T1C architecture can be improved, and the storage performance of the DRAM memory can be further improved.

In some embodiments, forming the capacitor coupled to the transistor includes the following operations.

The first electrode plate is formed, in which a shape of the first electrode plate includes a cylindrical shape, an axial direction of the first electrode plate with a cylindrical shape is parallel to the first direction parallel to the substrate.

The interelectrode dielectric layer covering the first electrode plate is formed.

The second electrode plate covering the interelectrode dielectric layer is formed; in which a shape of the second electrode plate includes a cylindrical shape, an axial direction of the second electrode plate with a cylindrical shape is parallel to the first direction, and the radius of the second electrode plate with a cylindrical shape is smaller than the radius of the first electrode plate with a cylindrical shape.

In practice, a capacitor hole may be formed by etching, for example, by dry etching, such as ion milling etching, plasma etching, reactive ion etching, laser ablation or the like. The first electrode plate with a cylindrical shape is formed in the capacitor hole, and the interelectrode dielectric layer is formed on the first electrode plate. The first electrode plate and the interelectrode dielectric layer may be formed in sequence by one or more deposition processes including, but not limited to, physical vapor deposition, chemical vapor deposition, atomic layer deposition, or any combination thereof. For example, the first electrode plate and the interelectrode dielectric layer may be formed by atomic layer deposition.

Here, the material of the first electrode plate may be a metal or a semiconductor conductive material, such as copper, cobalt, tungsten, doped silicon, polysilicon or any combination thereof. The material of the interelectrode dielectric layer may be a dielectric material, such as silicon dioxide, alumina or the like.

In practice, the process of forming the second electrode plate can refer to the process of forming the first electrode plate. The second electrode plate may be formed by a process including, but not limited to, physical vapor deposition, chemical vapor deposition, atomic layer deposition, or any combination thereof. For example, the second electrode plate may be formed by atomic layer deposition. In practice, the material of the second electrode plate may be a metal or a semiconductor conductive material, such as copper, cobalt, tungsten, molybdenum, doped silicon, polysilicon or any combination thereof.

In another embodiment, the shape of the capacitor further includes a planar shape, and the capacitor with a planar shape includes a first electrode plate, an interelectrode dielectric layer and a second electrode plate stacked in sequence, in which the first electrode plate, the interelectrode dielectric layer and the second electrode plate are parallel to each other. It could be understood that when the relative area of the first electrode plate and the second electrode plate is constant, the space occupied by the capacitor with a cylindrical shape is smaller than that of the capacitor with a planar shape, which is beneficial to further improve the integration of the memory. On the basis of this, in practice, capacitors with a cylindrical shape are used.

The semiconductor device manufactured by the method for manufacturing a semiconductor device provided by the embodiments of the disclosure is similar to the semiconductor device in the above-mentioned embodiment. Technical features not disclosed in detail in the embodiments of the disclosure are understood with reference to the above-mentioned embodiment, and will not be repeated here.

The descriptions above are only some specific embodiments of the present disclosure, and are not intended to limit the scope of protection of the embodiments of the present disclosure. Any change and replacement is easily to think within the technical scope of the embodiments of the present by those skilled in the art, and fall with the protection scope of the present disclosure.

1. A semiconductor device comprising: an insulating layer, a transistor located on the insulating layer and a conductive structure,
the transistor comprising a source, a channel and a drain arranged in parallel, and a gate dielectric layer and a gate structure, the gate dielectric layer being located between the gate structure and the channel; and
the conductive structure covering one sidewall of the channel and being used for grounding, and
the gate structure being disposed around the other three sidewalls of the channel, and the gate structure and the conductive structure being isolated from each other.

2. The semiconductor device according to claim 1, wherein the source, the channel and the drain are arranged in parallel along a first direction which is parallel to the insulating layer; and
wherein the semiconductor device comprises two said transistors arranged in parallel along a second direction which is parallel to the insulating layer, and intersects with the first direction; and
the conductive structure is located between the channels of the two transistors arranged in parallel along the second direction, and is electrically connected with both the channels of the two transistors arranged in parallel along the second direction.

3. The semiconductor device according to claim 1, wherein the source, the channel and the drain are arranged in parallel in a first direction which is parallel to the insulating layer; and
wherein the semiconductor device comprises two transistors arranged in parallel along a third direction, which is perpendicular to the insulating layer; and
the conductive structure is located at the same side of the channels of the two transistors arranged in parallel along the third direction, and is electrically connected with both the channels of the two transistors arranged in parallel along the second direction which is parallel to the insulating layer.

4. The semiconductor device structure according to claim 1, wherein,
the gate structure comprises a connecting layer and a conductive layer, the connecting layer being located between the gate dielectric layer and the conductive layer, and used for increasing an adhesion between the conductive layer and the gate dielectric layer.

5. The semiconductor device according to claim 1, wherein along a second direction parallel to the insulating layer, the channel comprises a first part and a second part, wherein,
in a plane parallel to the insulating layer, a projection of the first part is located in a projection of the gate structure, and a projection of the second part is located outside the projection of the gate structure; and
in a third direction perpendicular to the insulating layer, a dimension of the first part is smaller than a dimension of the second part.

6. The semiconductor device according to claim 1, wherein,
the transistor is N-type; and
a composition material of the conductive structure comprises a P-type semiconductor material.

7. The semiconductor device according to claim 1, comprising,
a memory cell array comprising a plurality of memory cell rows spaced apart from each other along a second direction and a plurality of memory cell columns spaced apart from each other along a third direction, the second direction being parallel to the insulating layer, the third direction being perpendicular to the insulating layer, each of the memory cell rows comprising a plurality of memory cells arranged in parallel along the third direction, each of the memory cell columns comprising a plurality of memory cells arranged in parallel along the second direction, and each of the memory cells comprising the transistor;
a plurality of word lines spaced apart from each other along the second direction, respectively coupled to the gate structures of a plurality of the transistors included in the memory cell rows; and
a plurality of bit lines spaced apart away each other along the third direction, respectively coupled to the drains of a plurality of the transistors included in the memory cell columns.

8. The semiconductor device according to claim 7, wherein,
each of the memory cells further comprises a capacitor comprising a first electrode plate, an interelectrode dielectric layer and a second electrode plate, the first electrode plate being in contact with the source, and the interelectrode dielectric layer electrically isolating the first electrode plate and the second electrode plate.

9. The semiconductor device according to claim 8, wherein,
a shape of the first electrode plate comprises a cylindrical shape, an axial direction of the first electrode plate with a cylindrical shape being parallel to the first direction which is parallel to the insulating layer; and
a shape of the second electrode plate comprises a cylindrical shape, an axial direction of the second electrode plate with a cylindrical shape is parallel to the first direction, wherein a radius of the second electrode plate with a cylindrical shape is smaller than a radius of the first electrode plate with a cylindrical shape.

10. A method for manufacturing a semiconductor device, comprising:
providing a substrate;
forming a stacked structure covering the substrate, wherein the stacked structure comprises a sacrificial layer and an active layer alternately stacked in turn along a direction perpendicular to the substrate, the active layer being used for forming a channel of a transistor;
etching the stacked structure along the direction perpendicular to the substrate to form first trenches which extend in a first direction parallel to the substrate;
forming a source at one end of the channel and forming a drain at another end of the channel along the first direction;
removing the sacrificial layer through the first trenches to form gaps;
filling the gaps and the first trenches with an insulating material to form an insulating structure;
forming a second trench penetrating the insulating structure in the direction perpendicular to the substrate to expose a first sidewall of the channel of the transistor, wherein the second trench extend along the first direction;
forming a conductive structure covering the exposed first sidewall through the second trench, wherein the conductive structure is used for grounding;
forming a third trench penetrating the insulating structure in the direction perpendicular to the substrate to expose another sidewall, opposite to the first sidewall, of the channel of the transistor;
removing exposed ends of the insulating material through the third trench to form first cavities extending in a second direction parallel to the substrate, wherein the insulating material is provided between the first cavities and the conductive structure; and
forming a gate dielectric layer and a gate structure in sequence on the other three sidewalls of the channels through the third trench and the first cavities, wherein the gate dielectric layer is located between the gate structure and the channel.

11. The method according to claim 10, wherein forming the conductive structure covering the exposed first sidewall through the second trench comprises:
forming a semiconductor filling layer in the second trench; and
performing a doping process on the semiconductor filling layer to form the conductive structure.

12. The method according to claim 10, wherein forming the gate dielectric layer and the gate structure in sequence on the other three sidewalls of the channel through the third trench and the first cavities comprises:
performing oxidation treatment on the sidewalls of the channel exposed by the third trench and the first cavities to form the gate dielectric layer; and
forming the gate structure covering the gate dielectric layer, wherein the channel comprises a first part and a second part in the second direction parallel to the substrate, and the gate dielectric layer covers the first part of the channel, in which in a plane parallel to the substrate, a projection of the first part is located in a projection of the gate structure, and a projection of the second part is located outside the projection of the gate structure; and in a third direction perpendicular to the substrate, the dimension of the first part is smaller than the dimension of the second part.

13. The method according to claim 12, wherein the gate structure comprises a connecting layer and a conductive layer, wherein the connecting layer is located between the gate dielectric layer and the conductive layer; and
wherein after the gate dielectric layer is formed, forming the gate structure covering the gate dielectric layer comprises:
forming a connecting layer covering the gate dielectric layer; and
forming the conductive layer covering the connecting layer, wherein the connecting layer is used for increasing an adhesion between the conductive layer and the gate dielectric layer.

14. The method according to claim 10, wherein a material of the sacrificial layer comprises silicon germanium, and a material of the active layer comprises silicon.

15. The method according to claim 10, comprising:
forming a memory cell array, wherein the memory cell array comprises a plurality of memory cell rows spaced apart from each other along the second direction and a plurality of memory cell columns spaced apart from each other along a third direction, the second direction is parallel to the substrate, the third direction is perpendicular to the substrate, each of the memory cell rows comprises a plurality of memory cells arranged in parallel along the third direction, each of the memory cell columns comprises a plurality of memory cells arranged in parallel along the second direction, and each of the memory cells comprising the transistor;
forming a plurality of word lines spaced apart from each other along the second direction, wherein the word lines are respectively coupled to the gate structures of a plurality of the transistors included in the memory cell rows; and
forming a plurality of bit lines spaced apart from each other along the third direction, wherein the bit lines are respectively coupled to the drains of a plurality of the transistors included in the memory cell columns.

16. The method according to claim 15, wherein forming the memory cell array comprises:
forming a capacitor coupled to each of the transistors, wherein the capacitor comprises a first electrode plate, an interelectrode dielectric layer and a second electrode plate, the first electrode plate is in contact with the source of the transistor, and the interelectrode dielectric layer electrically isolates the first electrode plate and the second electrode plate.

17. The method according to claim 16, wherein forming the capacitor coupled to each of the transistors comprises:
forming the first electrode plate, wherein a shape of the first electrode plate comprises a cylindrical shape, and an axial direction of the first electrode plate with a cylindrical shape being parallel to the first direction which is parallel to the substrate;
forming the interelectrode dielectric layer covering the first electrode plate; and
forming a second electrode plate covering the interelectrode dielectric layer, wherein a shape of the second electrode plate comprises a cylindrical shape, an axial direction of the second electrode plate with a cylindrical shape is parallel to the first direction, and a radius of the second electrode plate with a cylindrical shape is smaller than a radius of the first electrode plate with a cylindrical shape.
